(19) United States
(12) Patent Application Publication
(10) Pub. No.: US 2025/0160137 A1
(43) Pub. Date: May 15, 2025

(54) DISPLAY DEVICE

(71) Applicant: Samsung Display Co., LTD., Yongin-si (KR)

(72) Inventors: Jong Hwan CHA, Yongin-si (KR); Jin Yool KIM, Yongin-si (KR)

(73) Assignee: Samsung Display Co., LTD., Yongin-si (KR)

(21) Appl. No.: 18/742,136

(22) Filed: Jun. 13, 2024

(30) Foreign Application Priority Data
Nov. 14, 2023 (KR) 10-2023-0157097

(51) Int. Cl. H10K 59/124; H10K 59/131

(52) U.S. Cl. CPC H10K 59/124; H10K 59/131

(57) ABSTRACT

A display device includes a first conductive layer disposed on a substrate and including at least two metal layers, a first insulating film on the first conductive layer, a transistor on the first insulating film, a pixel electrode on the transistor, an emissive layer on the pixel electrode, a common electrode on the emissive layer, and a first blocking film disposed on a side surface of one of the at least two metal layers of the first conductive layer.

### CROSS-REFERENCE TO RELATED APPLICATION(S)

This application claims priority to and benefits of Korean Patent Application No. 10-2023-0157097 under 35 U.S.C. 119, filed on Nov. 14, 2023, in the Korean Intellectual Property Office (KIPO), the entire contents of which are incorporated herein by reference.

### BACKGROUND

### 1. Technical Field

The disclosure relates to a display device that can prevent adjacent conductive layers from being connected with each other due to damage to an insulating film.

### 2. Description of the Related Art

An organic light-emitting diode display, unlike a liquid-crystal display, is self-luminous. Accordingly, an organic light-emitting diode display does not require a separate light source and thus it can be made lighter and thinner. In addition, an organic light-emitting diode display has high-quality characteristics such as low power consumption, high luminance and fast response speed, and thus is attracting attention as the next generation display.

### SUMMARY

Aspects of the disclosure provide a display device that can prevent adjacent conductive layers from being connected with each other due to damage to an insulating film.

According to an embodiment of the disclosure, a display device may include a first conductive layer disposed on a substrate and including at least two metal layers, a first insulating film on the first conductive layer, a transistor on the first insulating film, a pixel electrode on the transistor; an emissive layer on the pixel electrode, a common electrode on the emissive layer, and a first blocking film disposed on a side surface of one of the at least two metal layers of the first conductive layer.

In an embodiment, the at least two metal layers may include a first metal layer on the substrate, a second metal layer on the first metal layer, and a third metal layer on the second metal layer.

In an embodiment, the first blocking film may be disposed on a side surface of the second metal layer.

In an embodiment, the first blocking film may surround the side surface of the second metal layer in a plan view.

In an embodiment, the first blocking film may be disposed on the side surface of the second metal layer between edges of the first metal layer and edges of the third metal layer.

In an embodiment, the second metal layer may be surrounded by the first metal layer, the third metal layer, and the first blocking film.

In an embodiment, each of the first metal layer and the third metal layer may include titanium, and the second metal layer may include aluminum.

In an embodiment, the at least two metal layers may include a first metal layer on the substrate, and a second metal layer on the first metal layer.

In an embodiment, the first blocking film may be disposed on a side surface of the second metal layer.

In an embodiment, the first blocking film may be further disposed on an upper surface of the second metal layer.

In an embodiment, the first blocking film may surround the side surface of the second metal layer in a plan view.

In an embodiment, the first blocking film may be disposed on the side surface of the second metal layer at edges of the first metal layer.

In an embodiment, the second metal layer may be surrounded by the first metal layer and the first blocking film.

In an embodiment, the at least two metal layers may include a first metal layer on the substrate, and a second metal layer on the first metal layer.

In an embodiment, the first blocking film may be disposed on a side surface of the first metal layer.

In an embodiment, the first blocking film may surround the side surface of the first metal layer in a plan view.

In an embodiment, the first blocking film may be disposed on the side surface of the first metal layer at edges of the second metal layer.

In an embodiment, the display device may further include a second insulating film disposed between the substrate and the first conductive layer. The first metal layer may be surrounded by the second insulating film, the second metal layer, and the first blocking film.

In an embodiment, the display device may further include a second conductive layer on the first insulating film.

In an embodiment, the second conductive layer may overlap the first conductive layer in a plan view.

In an embodiment, the second conductive layer may include at least two metal layers.

In an embodiment, the display device may further include a second blocking film disposed on a side surface of one of the at least two metal layers of the second conductive layer.

According to an embodiment of the disclosure, it may be possible to prevent adjacent conductive layers from being connected with each other due to damage to an insulating film in a display device.

The effects are not limited to those mentioned above and more various effects are included in the following description of the disclosure.

### BRIEF DESCRIPTION OF THE DRAWINGS

The above and other aspects and features of the disclosure will become more apparent by describing in detail embodiments thereof with reference to the attached drawings, in which:

FIG. 1 is a plan view showing a display device according to an embodiment of the disclosure.

FIG. 2 is a plan view showing the display panel of FIG. 1.

FIG. 3 is a schematic diagram of an equivalent circuit of a pixel according to an embodiment of the disclosure.

FIG. 4 is a schematic cross-sectional view showing a display panel according to an embodiment of the disclosure.

FIG. 5 is an enlarged view of portion A of the display device according to the embodiment of FIG. 4.

FIG. 6 is an enlarged view of portion A of the display device according to the embodiment of FIG. 4.

FIG. 7 is an enlarged view of portion A of the display device according to the embodiment of FIG. 4.

FIGS. 8 to 12 are schematic cross-sectional views for illustrating a method of fabricating a display device according to an embodiment of the disclosure.

FIG. 13 is a schematic cross-sectional view for illustrating a method of fabricating a display device according to an embodiment of the disclosure.

FIGS. 14 to 18 are schematic cross-sectional views for illustrating a method of fabricating a display device according to an embodiment of the disclosure.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art. It is to be noted that the scope of the disclosure is defined only by the claims.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Like reference numerals denote like elements throughout the descriptions. The figures, dimensions, ratios, angles, numbers of elements given in the drawings are merely illustrative and are not limiting.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Features of various embodiments of the disclosure may be combined partially or totally. As will be clearly appreciated by those skilled in the art, technically various interactions and operations are possible. Various embodiments can be practiced individually or in combination.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

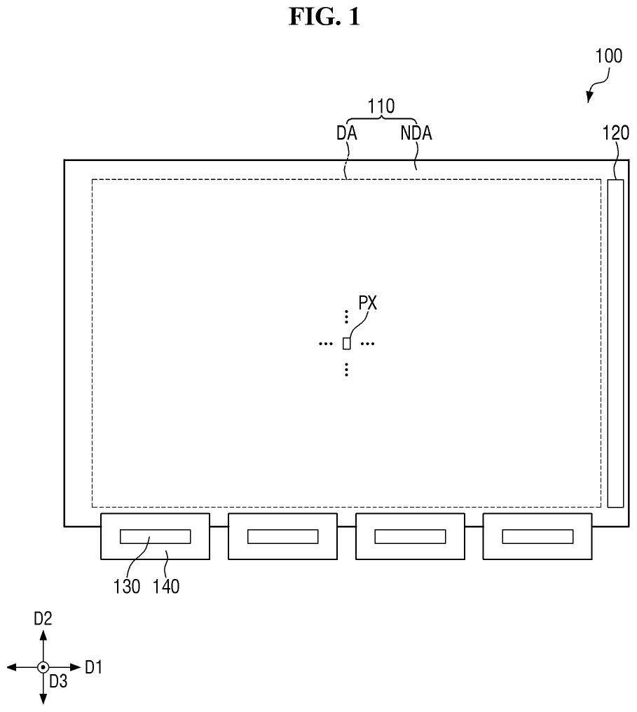

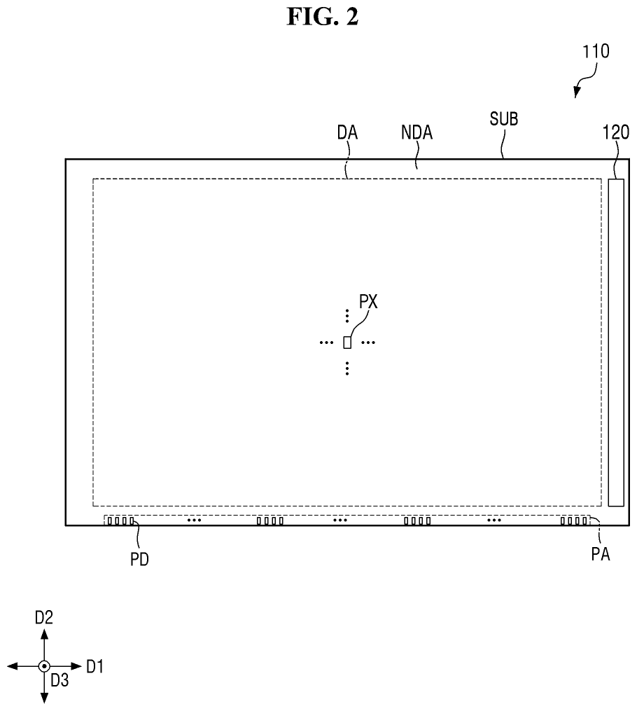

FIG. 1 is a plan view showing a display device 100 according to an embodiment of the disclosure. FIG. 2 is a plan view showing a display panel 110 of FIG. 1.

Referring to FIGS. 1 to 2, a display device 100 may display moving images or still images. The display device 1 may be used as a display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as a display screen of various products such as a television, a notebook, a monitor, a billboard and the Internet of Things (IoT). Those listed-above are merely as examples, and the display device 100 may be employed in other electronic devices as well.

According to an embodiment of the disclosure, the display device 100 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro or nano light-emitting diodes (micro LEDs or nano LEDs). It should be understood, however, that the disclosure is not limited thereto. For example, the display device 100 may be other types of display devices than light-emitting display devices. In the following description, a light-emitting display device (e.g., an organic light-emitting display device) is disclosed as an embodiment of the display device 100.

The display device 100 may include a display panel 110 including pixels PX, and a first driver 120 and a second driver 130 that supply driving signals to the pixels PX. The display device 100 may further include additional elements. For example, the display device 100 may further include a power supply unit for supplying supply voltages to the pixels PX, and a timing controller for controlling the operation of the first driver 120 and the second driver 130, etc.

The display panel 110 may include a display area DA and a non-display area NDA. The display area DA may include pixels PX to display images. For example, the display area DA may include pixel areas where the pixels PX are disposed. The non-display area NDA may be an area other than the display area DA, where no image is displayed. According to an embodiment of the disclosure, the non-display area NDA may be disposed around the display area DA and surround the display area DA in a plan view.

In FIGS. 1 and 2, a first direction D1, a second direction D2 and a third direction D3 are defined. According to an embodiment of the disclosure, the first direction D1 may be a horizontal direction of the display panel 110, and the second direction D2 may be a vertical direction of the display panel 110. The third direction D3 may be a thickness direction of the display panel 110.

According to an embodiment of the disclosure, the display panel 110 may have a rectangular shape in a plan view. Although the display panel 110 has a horizontal length greater than a vertical length in FIGS. 1 and 2, the shape of the display panel 110 is not limited thereto. For example, the display panel 110 may have a shape in which the vertical length is greater than the horizontal length, or may have a square shape, etc. The display panel 110 may include sharp corners or rounded corners.

The shape of the display panel 110 is not limited to the above-described rectangular shapes, and other shapes may be employed. For example, the display panel 110 may have a polygonal shape other than a rectangle, a circular shape, an elliptical shape, or other shapes.

According to an embodiment of the disclosure, the display panel 110 may be substantially flat on a plane defined by the first direction D1 and the second direction D2, and may have a uniform thickness in the third direction DR3. In another embodiment, the display panel 110 may have a three-dimensional shape having a curved surface, etc.

The display panel 110 may be a rigid display panel that is not substantially deformed, or a flexible display panel that can be deformed, i.e., at least partially folded, bent or rolled. The display panel 110 may be provided to the display device 100 without being bent or with being partially bent.

The display panel 110 may include a substrate SUB and pixels PX disposed on the substrate SUB. The pixels PX may be disposed in the display area DA on the substrate SUB.

The substrate SUB may be a base member for fabricating or providing the display panel 110 and may form a base surface of the display panel 110. The substrate SUB may include a display area DA and a non-display area NDA surrounding the display area DA in a plan view.

The display area DA may have a variety of shapes according to embodiments. For example, the display area DA may have a rectangular shape, a non-rectangular polygonal shape, a circular shape, an elliptical shape, an irregular shape, or other shapes in a plan view. According to an embodiment of the disclosure, the display area DA may have a shape that conforms to the shape of the display panel 110.

The pixels PX may be provided and/or arranged in the display area DA. For example, the display area DA may include multiple pixel areas where the pixels PX are disposed.

According to an embodiment of the disclosure, the display device 100 may be a light-emitting display device, and each of the pixels PX may include a light-emitting element located in the respective emission area and a pixel circuit connected to the light-emitting element. In the following description of the embodiments, the term “connection” may include electrical connection and/or physical connection. Each of the pixel circuits may include transistors (e.g., transistors including a driving transistor that generates a driving current corresponding to a data signal, and at least one switching transistor), and at least one capacitor (e.g., a capacitor including a storage capacitor).

The non-display area NDA may include a pad area PA where the pads PD are disposed. According to an embodiment of the disclosure, the non-display area NDA may further include a driver circuit area located on at least one side of the display area DA. At least one driver, pads PD and/or lines may be disposed in the non-display area NDA.

At least one driver for driving the pixels PX or a part of the driver may be disposed in the driver circuit area. For example, circuit elements forming the first driver 120 (e.g., driving transistors and driving capacitors forming stage circuits of the first driver 120) may be disposed in the driver circuit area on the substrate SUB. According to an embodiment of the disclosure, the circuit elements of the first driver 120 may be formed in the display panel 110 together with the pixels PX. According to an embodiment of the disclosure, the driving transistors provided to the first driver 120 may be transistors of substantially the same or similar type and/or structure as the transistors provided to the pixels PX, and may be formed together with transistors of the pixels PX.

Pads PD may be disposed in the pad area PA. At least one circuit board 140 may be disposed and/or bonded on the pad area PA. According to an embodiment of the disclosure, multiple circuit boards 140 connected to corresponding pads PD may be disposed in the pad area PA. The pads PD may include signal pads and power pads for transmitting the driving signals and the supply voltages required for driving the pixels PX and/or the first driver 120 to the inside of the display panel 110.

The first driver 120 and the second driver 130 may generate driving signals for controlling the operation timing and brightness of the pixels PX, and may supply the driving signals to the pixels PX. For example, the first driver 120 may be a gate driver including a scan driver, and may be connected to the pixels PX through corresponding gate lines. The first driver 120 may supply gate signals (e.g., control signals that control the operation timing of the pixels PX, including scan signals and/or emission control signals) to the pixels PX. The second driver 130 may be a data driver including source driver circuits and may be connected to the pixels PX through corresponding data lines. The second driver 130 may supply respective data signals to the pixels PX.

According to an embodiment of the disclosure, at least one of the first driver 120 and the second driver 130 or a part of the at least one driver may be incorporated into the display panel 110. For example, the first driver 120 or a part of the first driver 120 may be disposed on the substrate SUB of the display panel 110 and may be disposed and/or formed in the non-display area NDA.

Although the first driver 120 is formed on a side of the display area DA (for example, in the non-display area NDA on the right side of the display area DA) in FIG. 1, the disclosure is not limited thereto. In another embodiment, the first driver 120 may be located only on another side of the display area DA (for example, in the non-display area NDA on the left side of the display area DA), or located on sides of the display area DA (for example, in the non-display area NDA on the left and right sides of the display area DA). In another embodiment, a part of the first driver 120 may be located in the non-display area NDA, while another part of the first driver 120 may be located in a non-emission area (for example, an area between the emission areas of the pixels PX) in the display area DA.

According to an embodiment of the disclosure, another one of the first driver 120 and the second driver 130 or a part of the another driver may be disposed or formed outside the display panel 110 and may be electrically connected to the display panel 110. For example, the second driver 130 may be implemented with multiple integrated circuit chips and may be disposed on circuit boards 140 electrically connected to the pixels PX of the display panel 110. The second driver 130 may be implemented as at least one integrated circuit chip and may be mounted on the non-display area NDA of the display panel 110.

The circuit board 140 may be connected to the display panel 110 through the pads PD. According to an embodiment of the disclosure, the circuit board 140 may be, but is not limited to, a flexible printed circuit board (FPCB), a printed circuit board (PCB) or a flexible film such as chip on film (COF). According to an embodiment of the disclosure, the circuit boards 140 may be connected to a timing controller and/or a power supply unit through another circuit board or a connector.

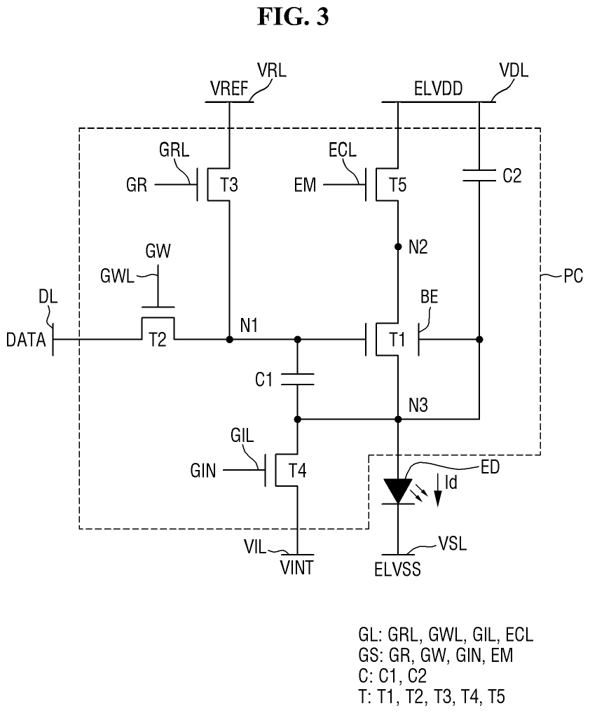

FIG. 3 is a schematic diagram of an equivalent circuit of a pixel PX according to an embodiment of the disclosure. For example, FIG. 3 schematically shows a pixel PX of a light-emitting display device including a light-emitting element ED. to the disclosure is not limited to the embodiment of FIG. 3, and the type and/or structure of the pixel PX in the display device 100 may vary depending on embodiments.

Referring to FIG. 3 in addition to FIGS. 1 and 2, the pixel PX may include a light-emitting element ED and a pixel circuit PC connected to the light-emitting element ED. The light-emitting element ED may be a light source of the pixel PX and may be, but is not limited to, an organic light-emitting diode. The pixel circuit PC may control the emission timing and brightness of the light-emitting element ED.

The pixel circuit PC may include transistors T and at least one capacitor C. For example, the pixel circuit PC may include first to fifth transistors T1 to T5, and first and second capacitors C1 and C2. Although FIG. 3 illustrates that all of the transistors T are n-type transistors, the types of the transistors T are not limited thereto. For example, at least one transistor T may be formed as a p-type transistor.

The pixel circuit PC may supply the driving current Id to the light-emitting element ED in response to the driving signals supplied from the first driver 120 and the second driver 130. For example, the pixel circuit PC may supply the driving current Id to the light-emitting element ED in response to the gate signals GS supplied from the first driver 120 through the respective gate lines GL and the data signal DATA supplied from the second driver 130 through the data lines DL.

The first transistor T1 may be a driving transistor of the pixel PX in which the magnitude of the drain-source current (e.g., driving current Id) is determined depending on the gate-source voltage. The second, third, fourth and fifth transistors T2, T3, T4 and T5 may be switching transistors that are turned on or off depending on the respective gate-source voltages. Depending on the type (e.g., p-type or n-type transistor) and/or operating conditions of each of the first to fifth transistors T1 to T5, the first electrode of each of the first to fifth transistors T1 to T5 may be a drain electrode (or drain region) or a source electrode (or source region) while the second electrode thereof may be an electrode different from the first electrode. For example, in case that the first electrode is a drain electrode, the second electrode may be a source electrode.

The pixel PX may be connected to a first gate line GWL transmitting a first gate signal GW (e.g., a scan signal), a second gate line GIL transmitting a second gate signal GIN, a third gate line GRL transmitting a third gate signal GR, an emission control line ECL transmitting an emission control signal EM, and a data line DL transmitting a data signal DATA. The pixel PX may be connected to a first voltage line VDL transmitting a first pixel voltage ELVDD (also referred to as “first pixel supply voltage”), and a second voltage line VSL transmitting a second pixel voltage ELVSS (also referred to as “second pixel supply voltage”). According to an embodiment of the disclosure, the pixel PX may be further connected to an initialization voltage line VIL transmitting an initialization voltage VINT (also referred to as “third pixel supply voltage”), and a reference voltage line VRL transmitting a reference voltage VREF (also referred to as “fourth pixel supply voltage”).

According to an embodiment of the disclosure, the first to fifth transistors T1 to T5 may be located in the respective pixel areas and may be oxide transistors (also referred to as “oxide semiconductor transistors”) including an oxide semiconductor (e.g., an oxide semiconductor material). For example, the active layer of each of the first to fifth transistors T1 to T5 may include an oxide semiconductor. It should be understood, however, that the disclosure is not limited thereto. For example, at least one transistor T may be formed of a semiconductor material other than an oxide semiconductor (e.g., amorphous silicon or polysilicon).

Oxide semiconductors have high carrier mobility and low leakage current, and accordingly, a large voltage drop may not occur even if an oxide transistor is driven for a long period of time. For example, the pixel PX including an oxide transistor may be driven at a low frequency because changes in brightness and/or color of images due to a voltage drop are ignorable even when driven at a low frequency. In case that the first to fifth transistors T1 to T5 are formed of oxide transistors, it is possible to suppress or prevent leakage current of the pixel PX and to save power consumption.

Oxide semiconductor may be sensitive to light, and thus the amount of current may change due to external light. According to an embodiment of the disclosure, a light-blocking pattern or a light-blocking electrode (e.g., a bottom electrode or a back-gate electrode) may be disposed under the active layer included in at least one transistor T to block external light. Accordingly, the operating characteristics of the transistor T may be stabilized.

The first transistor T1 may include a gate electrode connected to a first node N1, a first electrode (e.g., a drain electrode) connected to a second node N2, and a second electrode (e.g., a source electrode) connected to a third node N3. The first electrode of the first transistor T1 may be connected to the first voltage line VDL via a fifth transistor T5, and the second electrode may be connected to the light-emitting element ED. The first transistor T1 may control the magnitude (e.g., amount) of the driving current Id flowing to the light-emitting element ED in response to the data signal DATA transmitted to the first node N1.

According to an embodiment of the disclosure, the first transistor T1 may further include a bottom electrode BE connected to the third node N3 (e.g., a bottom-gate electrode or a back-gate electrode of the first transistor T1). The bottom electrode BE of the first transistor T1 may be connected to the third node N3 so that the first transistor T1 is implemented as a transistor with a double-gate structure (e.g., a double-gate transistor with a source-sync structure), thereby improving the operating characteristics of the first transistor T1.

The second transistor T2 may include a gate electrode connected to the first gate line GWL, a first electrode connected to the data line DL, and a second electrode connected to the first node N1. The second transistor T2 may be turned on by the first gate signal GW (e.g., the first gate signal GW of a gate-on voltage) transmitted from the first gate line GWL to connect the data line DL with the first node N1. Accordingly, the data signal DATA transmitted from the data line DL may be transmitted to the first node N1.

The third transistor T3 may include a gate electrode connected to the third gate line GRL, a first electrode connected to the reference voltage line VRL, and a second electrode connected to the first node N1. The third transistor T3 may be turned on by the third gate signal GR transmitted from the third gate line GRL and may transmit the reference voltage VREF from the reference voltage line VRL to the first node N1.

The fourth transistor T4 may include a gate electrode connected to the second gate line GIL, a first electrode connected to the third node N3, and a second electrode connected to the initialization voltage line VIL. The fourth transistor T4 may be turned on by the second gate signal GIN transmitted from the second gate line GIL, and may transmit the initialization voltage VINT from the initialization voltage line VIL to the third node N3.

The fifth transistor T5 may include a gate electrode connected to the emission control line ECL, a first electrode connected to the first voltage line VDL, and a second electrode (or the first electrode of the first transistor T1) connected to the second node N2. The fifth transistor T5 may be turned on by the emission control signal EM (e.g., the emission control signal EM of the gate-on voltage) from the emission control line ECL to control the timing of emission of the pixel PX.

Each of the second to fifth transistors T2 to T5 may or may not include a bottom electrode. According to an embodiment of the disclosure, at least one of the second to fifth transistors T2 to T5 may include a bottom electrode, and the bottom electrode of the at least one switching transistor may be connected to the gate electrode of that switching transistor. By connecting the bottom electrode of a switching transistor to the gate electrode, the off characteristics and switching speed of the switching transistor may be improved, an additional voltage tolerance range may be obtained, leakage current may be reduced, and voltage stability may be improved. For example, the operating characteristics of the switching transistor, which is formed of an oxide transistor with a short channel length, may be improved by forming a double-gate structure such as a gate-sync architecture.

A first capacitor CI may be connected between the first node N1 and the third node N3. The first capacitor C1 may be a storage capacitor of the pixel PX and may store a threshold voltage of the first transistor T1 and a voltage corresponding to a data signal DATA (e.g., data voltage).

A second capacitor C2 may be connected between the first voltage line VDL and the third node N3. According to an embodiment of the disclosure, the capacitance of the second capacitor C2 may be smaller than the capacitance of the first capacitor C1.

The light-emitting element ED may be connected between the third node N3 and the second voltage line VSL. For example, the light-emitting element ED may include a first electrode (e.g., anode electrode) connected to the third node N3, a second electrode (e.g., cathode electrode) facing the first electrode and connected to the second voltage line VSL, and an emissive layer interposed between the first electrode and the second electrode. According to an embodiment of the disclosure, the first electrode of the light-emitting element ED may be an individual electrode disposed separately in each of the pixels PX, and the second electrode of the light-emitting element ED may be a common electrode shared by multiple pixels PX. The light-emitting element ED may emit light with a brightness in proportional to the driving current Id supplied from the pixel circuit PC.

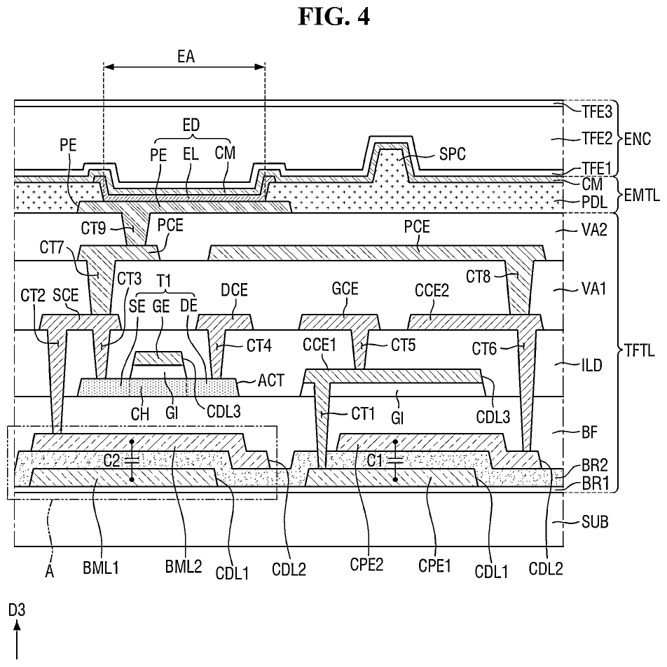

FIG. 4 is a schematic cross-sectional view showing the display panel 110 according to an embodiment of the disclosure. For example, FIG. 4 schematically shows a portion of the display area DA of the display panel 110. FIG. 4 schematically shows a light-emitting display panel including a light-emitting element ED (e.g., an organic light-emitting diode) as an embodiment of the display panel 110.

As shown in FIG. 4, the display device 10 may include a substrate SUB, a thin-film transistor layer TFTL, an emission material layer EMTL, and an encapsulation layer ENC. The thin-film transistor layer TFTL, the emission material layer EMTL and the encapsulation layer ENC may be sequentially disposed on the substrate SUB in the third direction D3. The thin-film transistor layer TFTL may include the first transistor T1, the second transistor T2, the third transistor T3, the fourth transistor T4, the first capacitor C1, and the second capacitor C2.

The substrate SUB may be a rigid substrate or a flexible substrate that can be bent, folded, rolled, etc. The substrate SUB may be made of an insulating material such as glass, quartz and a polymer resin. For example, the substrate SUB may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. In another embodiment, the first substrate SUB may include a metal material.

A first barrier layer BR1 may be disposed on the substrate SUB. The first barrier layer BR1 may be disposed on an entire surface of the substrate SUB. The first barrier layer BR1 may be a film for protecting the thin-film transistors T1 to T8 of the thin-film transistor layer TFTL and an emissive layer EL of the emission material layer EMTL from the moisture permeating through the substrate SUB that is vulnerable to moisture. The first barrier layer BR1 may be made up of multiple inorganic films alternately stacked each other. For example, the first barrier layer BR1 may be made up of multiple layers in which one or more inorganic layers of a silicon nitride layer, a silicon oxynitride layer, a silicon oxide layer, a titanium oxide layer and an aluminum oxide layer are alternately stacked each other.

A first conductive layer CDL1 may be disposed on the first barrier layer BR1. The first conductive layer CDL1 may include a first light-blocking layer BML1 and a first capacitor electrode CPE1. The first light-blocking layer BML1 and the first capacitor electrode CPE1 may be formed as one body. The first conductive layer CDL1 may be formed of, for example, a metal material such as chromium (Cr) and molybdenum (Mo), or black ink or black dye. The first conductive layer CDL1 may receive constant voltage. Accordingly, the first conductive layer CDL1 may not be electrically floating, and the electrical characteristics of the transistors on the first conductive layer CDL1 may be stabilized.

A second barrier layer BR2 may be disposed on the first conductive layer CDL1. For example, the second barrier layer BR2 may be disposed on the first light-blocking layer BML1 and the first capacitor electrode CPE1. The second barrier layer BR2 and the first barrier layer BR1 may have a same material and configuration.

A second conductive layer CDL2 may be disposed on the second barrier layer BR2. The second conductive layer CDL2 may include a second light-blocking layer BML2 and a second capacitor electrode CPE2. The second light-blocking layer BML2 and the second capacitor electrode CPE2 may be formed as one body. The second light-blocking layer BML2 may be disposed on the second barrier layer BR2 and overlap the first light-blocking layer BML1 in a plan view. The second capacitor electrode CPE2 may be disposed on the first capacitor electrode CPE1 and overlap the first capacitor electrode CPE in a plan view. The first capacitor C1 may be formed where the first capacitor electrode CPE1 and the second capacitor electrode overlap each other in a plan view. The second capacitor C2 may be formed where the first light-blocking layer BML1 and the second light-blocking layer BML2 overlap each other in a plan view.

A buffer layer BF may be disposed on the second conductive layer CDL2. For example, the buffer layer BF may be disposed on the second light-blocking layer BML2 and the second capacitor electrode CPE2. The buffer layer BF may be a layer for protecting the thin-film transistors T1 to T5 of the thin-film transistor layer TFTL and an emissive layer EL of the emission material layer EMTL from the moisture permeating through the substrate SUB that is vulnerable to moisture. The buffer layer BF may be formed of multiple inorganic layers alternatively stacked with each other. For example, the buffer layer BF may be made up of multiple layers in which one or more inorganic layers of a silicon nitride layer, a silicon oxynitride layer, a silicon oxide layer, a titanium oxide layer, and an aluminum oxide layer are alternately stacked with each other.

The active layer ACT may be disposed on the buffer layer BF. For example, the active layer ACT may be disposed on the buffer layer BF and overlap the second light-blocking layer BML2 in a plan view. The active layer ACT may be made of low-temperature polycrystalline silicon (LTPS). In another embodiment, the active layer ACT may be an oxide-based active layer ACT. For example, the active layer ACT may be an oxide semiconductor such as indium-gallium-zinc-oxide (IGZO) or indium-gallium-zinc-tin oxide (IGZTO).

A gate insulator GI may be disposed on each of the active layer ACT and the buffer layer BF. For example, the gate insulator GI may be disposed on a channel region CH and overlap the channel region CH of the active layer ACT in a plan view. The gate insulator GI may be disposed on the buffer layer BF and overlap the second capacitor electrode CPE2 of the second conductive layer CDL2 in a plan view. The gate insulator GI may include at least one of tetraethoxysilane (TetaraEthylOrthoSilicate, TEOS), silicon nitride (SiNx), and silicon oxide (SiO₂). For example, the gate insulator GI may have a double layer structure in which a silicon nitride film having a thickness of about 40 nm and a tetracthoxysilane layer having a thickness of about 80 nm are stacked on one another.

A third conductive layer CDL3 may be disposed on the gate insulator GI. The third conductive layer CDL3 may include a gate electrode GE and a first capacitor connection electrode CCE1. The gate electrode GE and the first capacitor connection electrode CCE1 may be formed as one body. The gate electrode GE may be disposed on the gate insulator GI and overlap the channel region CH in a plan view, and the first capacitor connection electrode CCE1 may be disposed on the gate insulator GI disposed on the buffer layer BF. The first capacitor connection electrode CCE1 may be connected to the first capacitor electrode CPE1 through a first contact hole CT1 penetrating the gate insulator GI, the buffer layer BF and the second barrier layer BR2.

An interlayer dielectric layer ILD may be disposed on the third conductive layer CDL3. The interlayer dielectric layer ILD may include an inorganic layer, for example, a silicon nitride layer, a silicon oxynitride layer, a silicon oxide layer, a titanium oxide layer, or an aluminum oxide layer. The interlayer dielectric layer ILD may include multiple inorganic films.

A source connection electrode SCE, a drain connection electrode DCE, a gate connection electrode GCE, and a second capacitor connection electrode CCE2 may be disposed on the interlayer dielectric layer ILD. A side of the source connection electrode SCE may be connected to the second light-blocking layer BML2 through a second contact hole CT2 penetrating the interlayer dielectric layer ILD and the buffer layer BF. Another side of the source connection electrode SCE may be connected to the source electrode SE of the active layer ACT through a third contact hole CT3 penetrating the interlayer dielectric layer ILD. The drain connection electrode DCE may be connected to the drain electrode DE of the active layer ACT through a fourth contact hole CT4 penetrating the interlayer dielectric layer ILD. The drain connection electrode DCE may be connected to the first capacitor connection electrode CCE1 through a fifth contact hole CT5 penetrating the interlayer dielectric layer ILD. The second capacitor connection electrode CCE2 may be connected to the second capacitor electrode CPE2 through a sixth contact hole CT6 penetrating the interlayer dielectric layer ILD and the buffer layer BF.

A first planarization layer VA1 may be disposed on the source connection electrode SCE, the drain connection electrode DCE, the gate connection electrode GCE, and the second capacitor connection electrode CCE2. The first planarization layer VIAI may include an organic film including an acryl resin, an epoxy resin, a phenolic resin, a polyamide resin, a polyimide resin, or a combination thereof.

A pixel connection electrode PCE may be disposed on the first planarization layer VA1. A side of the pixel connection electrode PCE may be connected to the source connection electrode SCE through a seventh contact hole CT7 penetrating the first planarization layer VA1. Another side of the pixel connection electrode PCE may be connected to the second capacitor connection electrode CCE2 through an eighth contact hole CT8 penetrating the first planarization layer VA1.

A second planarization layer VA2 may be disposed on the pixel connection electrode PCE. The second planarization layer VA2 and the first planarization layer VAI may include a same material and structure.

The emission material layer EMTL may be disposed on the second planarization layer VA2. The emission material layer EMTL may include a pixel-defining layer PDL and a light-emitting element ED stacked in the third direction D3. The light-emitting element ED may include a pixel electrode PE, an emissive layer EL, and a common electrode CM.

The pixel electrode PE of the light-emitting element ED may be disposed on the second planarization layer VA2. The pixel electrode PE may be connected to the pixel connection electrode PCE through a ninth contact hole CT9 penetrating the second planarization layer VA2.

In the emission area EA, the pixel electrode PE, the emissive layer EL, and the common electrode CM may be stacked on one another sequentially, and holes from the pixel electrode PE and electrons from the common electrode CM may be combined with each other in the emissive layer EL to emit light. The pixel electrode PE may be an anode electrode of the light-emitting element ED, and the common electrode CM may be a cathode electrode of the light-emitting element ED.

In the top-emission structure where light exits from the emissive layer EL toward the common electrode CM, the pixel electrode PE may be have a single layer including molybdenum (Mo), titanium (Ti), copper (Cu) or aluminum (Al), or may have a stack structure of aluminum and titanium (Ti/Al/Ti), a stack structure of aluminum and ITO (ITO/AI/ITO), an APC alloy, and a stack structure of APC alloy and ITO (ITO/APC/ITO) in order to increase the reflectivity. The APC alloy may be an alloy of silver (Ag), palladium (Pd) and copper (Cu).

The pixel-defining layer PDL may define the emission area EA of the pixel. To this end, the pixel-defining layer PDL may be formed on the second passivation film PAS2 and expose a part of the pixel electrode PE. The pixel-defining layer PDL may cover the edges of the pixel electrode PE.

The pixel-defining film PDL may be formed of an organic layer including an acryl resin, an epoxy resin, a phenolic resin, a polyamide resin, a polyimide resin, or a combination thereof.

The spacer SPC may be disposed on the pixel-defining layer PDL. The spacer SPC may support a mask during a process of fabricating the emissive layer EL. The spacer SPC may be formed of an organic film including an acryl resin, an epoxy resin, a phenolic resin, a polyamide resin, a polyimide resin, or a combination thereof. According to an embodiment of the disclosure, the spacer SPC and the pixel-defining layer PDL may be integral with each other. In other words, the spacer SPC and the pixel-defining layer PDL may be made of a same material.

The emissive layer EL may be disposed on the pixel electrode PE. The emissive layer EL may include an organic material to emit light of a color. For example, the emissive layer EL may include a hole transporting layer, an organic material layer, and an electron transporting layer. The organic material layer may include a host and a dopant. The organic material layer may include a material that emits a light, and may be formed using a phosphor or a fluorescent material.

For example, the organic material layer of the emissive layer EL, which emits light of a first color (e.g., blue), may be, but is not limited to, a phosphor that includes a host material including CBP or mCP, and a dopant material including (4,6-F2ppy) 2Irpic or L2BD111.

The organic material layer of the emissive layer EL, which emits light of a second color (e.g., green), may be a phosphor that includes a host material including CBP or mCP, and a dopant material including ir (ppy) 3 (fac tris(2-phenylpyridine) iridium). In another embodiment, the organic material layer of the emissive layer EL, which emits light of the second color may be, but is not limited to, a fluorescent material including Alq3 (tris(8-hydroxyquinolino)aluminum).

The organic material layer of the emissive layer EL that emits light of the third color (e.g., red) may be a phosphor that includes a host material including carbazole biphenyl (CBP) or mCP (1,3-bis(carbazol-9-yl), and a dopant including at least one of PIQIr (acac) (bis(1-phenylisoquinoline) acetylacetonate iridium), PQIr (acac) (bis(1-phenylquinoline) acetylacetonate iridium), PQIr (tris(1-phenylquinoline) iridium) and PtOEP (octaethylporphyrin platinum). In another embodiment, the organic material layer of the emissive layer EL, which emits light of the third color, may be, but is not limited to, a fluorescent material including PBD: Eu (DBM) 3 (Phen) or perylene.

The common electrode CM may be disposed on the emissive layer EL. The common electrode CM may be disposed on and cover the emissive layer EL. The common electrode CM may be a common layer disposed across multiple emissive layers EL. A capping layer may be formed on the common electrode CM.

In the top-emission structure, the common electrode CM may be formed of a transparent conductive material (TCP) such as ITO and IZO that can transmit light, or a semi-transmissive conductive material such as magnesium (Mg), silver (Ag), and an alloy of magnesium (Mg) and silver (Ag). In case that the common electrode CM is formed of a semi-transmissive metal material, the light extraction efficiency may be increased by using microcavities.

The encapsulation layer ENC may be formed on the emission material layer EMTL. The encapsulation layer ENC may include one or more inorganic films TFEL and TFE3 to prevent permeation of oxygen or moisture into the emission material layer EMTL. The encapsulation layer ENC may include at least one organic film to protect the emission material layer EMTL from particles such as dust. For example, the encapsulation layer ENC may include a first inorganic encapsulation film TFE1, an organic encapsulation film TFE2, and a second inorganic encapsulation film TFE3.

The first inorganic encapsulation film TFEl may be disposed on the common electrode CM, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may be made up of multiple layers in which one or more inorganic layers of a silicon nitride layer, a silicon oxynitride layer, a silicon oxide layer, a titanium oxide layer, and an aluminum oxide layer are alternately stacked each other. The organic encapsulation film TFE2 may be an organic film including an acryl resin, an epoxy resin, a phenolic resin, a polyamide resin, a polyimide resin, etc.

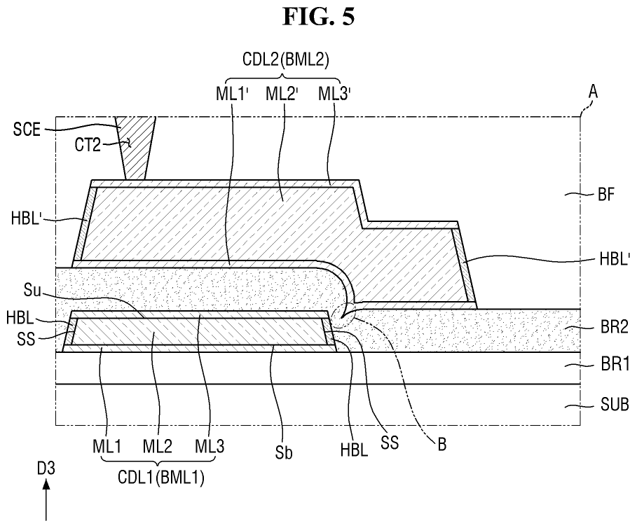

FIG. 5 is an enlarged view of portion A of the display device according to an embodiment of FIG. 4.

As shown in FIG. 5, the first conductive layer CDL1 may include a first metal layer ML1, a second metal layer ML2, and a third metal layer ML3. For example, the first light-blocking layer BML1 of the first conductive layer CDL1 may include the first metal layer ML1, the second metal layer ML2, and the third metal layer ML3 sequentially stacked on the first barrier layer BR1 in the third direction D3.

The first metal layer ML1 may be disposed on the first barrier layer BR1. For example, the first metal layer ML1 may be disposed between the first barrier layer BR1 and the second metal layer ML2. The first metal layer ML1 may be made of a material containing titanium (Ti).

The second metal layer ML2 may be disposed on the first metal layer ML1. For example, the second metal layer ML2 may be disposed between the first metal layer ML1 and the third metal layer ML3. The thickness of the second metal layer ML2 may be greater than the thickness of the first metal layer ML1 (or the second metal layer ML2). The thickness may be in the third direction D3. The second metal layer ML2 may be made of a material containing aluminum (Al), for example.

The third metal layer ML3 may be disposed on the second metal layer ML2. For example, the third metal layer ML3 may be disposed between the second metal layer ML2 and the second barrier layer BR2. The thickness of the third metal layer ML3 may be equal to the thickness of the first metal layer ML1 described above. The third metal layer ML3 and the first metal layer ML1 may be made of a same material. For example, the third metal layer ML3 may be made of a material containing titanium (Ti).

A blocking film HBL may be disposed on side surfaces Ss of the second metal layer ML2. For example, the blocking film HBL may be disposed on side surfaces Ss of the second metal layer ML2, wherein the surfaces of the second metal layer ML2 that face each other in the third direction D3 (or the thickness direction of the second metal layer ML2) may be defined as a lower surface Sb and an upper surface Su of the second metal layer ML2, respectively, and the surfaces located between the lower surface Sb and the upper surface Su may be defined as the side surfaces Ss. The lower surface Sb of the second metal layer ML2 may be disposed closer to the substrate SUB than the upper surface Su. An area of the lower surface Sb of the second metal layer ML2 may be greater than an area of the upper surface Su. The above-described first metal layer ML1 may be disposed on the lower surface Sb of the second metal layer ML2, and the third metal layer ML3 may be disposed on the upper surface Su of the second metal layer ML2. The first metal layer ML1 may be in contact with the lower surface Sb of the second metal layer ML2, and the third metal layer ML3 may be in contact with the upper surface Su of the second metal layer ML2. The second metal layer ML2 may have a diagonal shape in a cross-sectional view, and the side surfaces Ss of the second metal layer ML2 may be inclined at an angle with respect to the lower surface Sb of the second metal layer ML2.

According to an embodiment of the disclosure, the blocking film HBL may be disposed along the side surfaces of the second metal layer ML2.

According to an embodiment of the disclosure, the blocking film HBL may be in contact with the side surfaces of the second metal layer ML2.

According to an embodiment of the disclosure, the blocking film HBL may have the shape of a closed curve surrounding the second metal layer ML2 in a plan view. For example, the blocking film HBL may have a ring shape surrounding the second metal layer ML2.

According to an embodiment of the disclosure, the blocking film HBL may be disposed between the first metal layer ML1 and the third metal layer ML3. For example, the blocking film HBL may surround the second metal layer ML2 between the first metal layer ML1 and the third metal layer ML3.

According to an embodiment of the disclosure, the first metal layer ML1 may have a larger area than the lower surface Sb of the second metal layer ML2 in a plan view. The edges (e.g., tips) of the first metal layer ML1 may extend over the edges of the second metal layer ML2 and may not overlap the second metal layer ML2 in a plan view. For example, the edges of the first metal layer ML1 may surround the edges of the lower surface Sb of the second metal layer ML2 in a plan view.

According to an embodiment of the disclosure, the third metal layer ML3 may have a greater area than the upper surface Su of the second metal layer ML2 in a plan view. The edges (e.g., tips) of the third metal layer ML3 may extend over the edges of the second metal layer ML2 and may not overlap the second metal layer ML2 in a plan view. For example, the edges of the third metal layer ML3 may surround the edges of the upper surface Su of the second metal layer ML2 in a plan view.

According to an embodiment of the disclosure, the blocking film HBL may be disposed between the edges (e.g., tips) of the first metal layer ML1 and edges (e.g., tips) of the third metal layer ML3. For example, the blocking film HBL may surround the second metal layer ML2 at the edges of the first metal layer ML1 and the edges of the third metal layer ML3.

According to an embodiment of the disclosure, the blocking film HBL may include an insulating film. For example, the blocking film HBL may include at least one of AlO and Al₂O₃.

According to an embodiment of the disclosure, the blocking film HBL may be formed on the side surfaces Ss of the second metal layer ML2 by natural oxidation. For example, after the first conductive layer CDL1 is formed, the first conductive layer CDL1 may be exposed (or left) to the air for a long time, so that an oxide film may be formed on the exposed side surfaces Ss of the second metal layer ML2. The oxide film may work as the above-described blocking film HBL.

According to an embodiment of the disclosure, the blocking film HBL may be formed by anodic oxidation. For example, the blocking film HBL may be formed by forming the first conductive layer CDL1 and oxidizing the exposed side surfaces Ss of the second metal layer ML2 by anodic oxidation.

According to an embodiment of the disclosure, the blocking film HBL may be formed by O2 ashing. For example, the blocking film HBL may be formed by forming the first conductive layer CDL1 and oxidizing the exposed side surfaces Ss of the second metal layer ML2 by O2 ashing.

According to an embodiment of the disclosure, the blocking film HBL may be formed by steam dry. For example, the blocking film HBL may be formed on the exposed side surfaces Ss of the second metal layer ML2 by forming the first conductive layer CDL1 and supplying moisture (e.g., H2) to the first conductive layer CDL1 by steam dry.

According to an embodiment of the disclosure, as shown in FIG. 5, the second metal layer ML2 of the first conductive layer CDL1 may be surrounded by the first metal layer ML1, the third metal layer ML3, and the blocking film HBL. In other words, the second metal layer ML2 may be disposed in a defined area surrounded by the first metal layer ML1, the third metal layer ML3, and the blocking film HBL (hereinafter referred to as a first shielded area). Accordingly, the second metal layer ML2 in the first shielded area may be isolated from the outside of the first shielded area by the first metal layer ML1, the third metal layer ML3, and the blocking film HBL.

The second conductive layer CDL2 and the first conductive layer CDL1 may have a same structure. For example, the second light-blocking layer BML2 of the second conductive layer CDL2 may include a first metal layer ML1′, a second metal layer ML2′, and a third metal layer ML3′. The first metal layer MLl′, the second metal layer ML2′, and the third metal layer ML3′ of the second conductive layer CDL2 may be identical to the first metal layer ML1, the second metal layer ML2, and the third metal layer ML3 of the first conductive layer CDL1, respectively; and, therefore, the redundant descriptions will be omitted.

A blocking film HBL′ surrounding the side surfaces of the second metal layer ML2′ of the second conductive layer CDL2 may be identical to the blocking film HBL surrounding the side surfaces Ss of the second metal layer ML2 of the first conductive layer CDL1, and, therefore, the redundant descriptions will be omitted.

The second metal layer ML2′ of the second conductive layer CDL2 may be disposed in a defined area surrounded by the first metal layer ML1′, the third metal layer ML3′, and the blocking film HBL′ of the second conductive layer CDL2 (hereinafter referred to as a second shielded area). Accordingly, the second metal layer ML2′ in the second shielded area may be isolated from the outside of the second shielded area by the first metal layer MLl′, the third metal layer ML3′, and the blocking film HBL′.

As described above, since the second metal layer ML2 in the first shielded area and the second metal layer ML2′ in the second shielded area are shielded from the outside, the hydrogen path between the second metal layer ML2 of the first shielded area and the second metal layer ML2′ of the second shielded area may be blocked even though the first conductive layer CDL1 and the second conductive layer CDL2 are disposed adjacent to each other and overlap each other in the third direction D3. Therefore, even if a hydrogen path is formed due to damage in an insulating film (e.g., the second barrier layer BR2) between the first conductive layer CDL1 and the second conductive layer CDL2 (e.g., seam, crack or pinhole at area B in the second barrier layer BR2), it may be possible to block movement of hydrogen from the second metal layer ML2 of the first conductive layer CDL1 to the second metal layer ML2′ of the second conductive layer CDL2 (or from the second metal layer ML2′ of the second conductive layer CDL2 to the second metal layer ML2 of the first conductive layer CDL1).

According to an embodiment of the disclosure, the hydrogen path between the adjacent conductive layers CDL1 and CDL2 may be blocked, so that it may be possible to prevent the adjacent conductive layers CDL1 and CDL2 from being connected with each other due to damage to the insulating film BR1, for example.

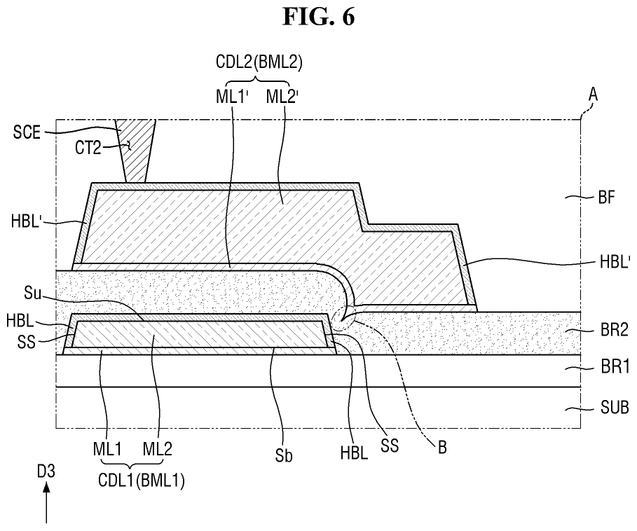

FIG. 6 is an enlarged view of portion A of the display device according to an embodiment of FIG. 4.

The display device of FIG. 6 may be different from the display device of FIG. 5 described above in the position of a blocking film HBL and the structure of conductive layers. The description will focus on the differences.

As shown in FIG. 6, the first conductive layer CDL1 may include a first metal layer ML1 and a second metal layer ML2. For example, the first light-blocking layer BML1 of the first conductive layer CDL1 may include the first metal layer ML1 and the second metal layer ML2 sequentially stacked on the first barrier layer BR1 in the third direction D3.

The blocking film HBL of FIG. 6 may be disposed on side surfaces Ss and an upper surface Su of the second metal layer ML2. For example, the blocking film HBL may surround the side surfaces Ss of the second metal layer ML2 and cover the upper surface Su of the second metal layer ML2 in a plan view. The blocking film HBL may be in contact with the side surfaces Ss and upper surface Su of the second metal layer ML2.

According to an embodiment of the disclosure, the blocking film HBL may be disposed on the edges of the first metal layer ML1. For example, the blocking film HBL may surround the side surfaces Ss of the second metal layer ML2 on the edges of the first metal layer ML1.

In this manner, the blocking film HBL of FIG. 6 may surround the exposed side surfaces Ss of the second metal layer ML2 like the above-described blocking film HBL of FIG. 5, and may further cover the exposed upper surface Su of the second metal layer ML2.

According to an embodiment of the disclosure, as shown in FIG. 6, the second metal layer ML2 of the first conductive layer CDL1 may be surrounded by the first metal layer ML1 and the blocking film HBL. In other words, the second metal layer ML2 may be disposed in a defined area surrounded by the first metal layer ML1 and the blocking film HBL (hereinafter referred to as a third shielded area). Accordingly, the second metal layer ML2 in the third shielded area may be isolated from the outside of the third shielded area by the first metal layer ML1 and the blocking film HBL.

The second conductive layer CDL2 and the first conductive layer CDL1 of FIG. 6 may have a same structure. For example, the second light-blocking layer BML2 of the second conductive layer CDL2 may include a first metal layer MLl′ and a second metal layer ML2′. The first metal layer MLl′ and the second metal layer ML2′ of the second conductive layer CDL2 may be identical to the first metal layer ML1 and the second metal layer ML2 of the first conductive layer CDL1, respectively; and, therefore, the redundant descriptions will be omitted.

A blocking film HBL′ surrounding the side surfaces of the second metal layer ML2 of the second conductive layer CDL2 may be identical to the blocking film HBL surrounding the side surfaces Ss of the second metal layer ML2 of the first conductive layer CDL1, and, therefore, the redundant descriptions will be omitted.

The second metal layer ML2′ of the second conductive layer CDL2 may be disposed in a defined area surrounded by the first metal layer ML1′ of the second conductive layer CDL2′ and the blocking film HBL′ (hereinafter referred to as a fourth shielded area). Accordingly, the second metal layer ML2′ in the fourth shielded area may be isolated from the outside of the fourth shielded area by the first metal layer MLl′ and the blocking film HBL′.

As described above, since the second metal layer ML2 in the third shielded area and the second metal layer ML2′ in the fourth shielded area are shielded from the outside, the hydrogen path between the second metal layer ML2 of the third shielded area and the second metal layer ML2′ of the fourth shielded area may be blocked even though the first conductive layer CDL1 and the second conductive layer CDL2 are disposed adjacent to each other and overlap each other in the third direction D3. Therefore, even if a hydrogen path is formed due to damage in an insulating film (e.g., the second barrier layer BR2) between the first conductive layer CDL1 and the second conductive layer CDL2 (e.g., seam, crack or pinhole at area B in the second barrier layer BR2), it may be possible to block movement of hydrogen from the second metal layer ML2 of the first conductive layer CDL1 to the second metal layer ML2′ of the second conductive layer CDL2 (or from the second metal layer ML2′ of the second conductive layer CDL2 to the second metal layer ML2 of the first conductive layer CDL1).

According to an embodiment of the disclosure, the hydrogen path between the adjacent conductive layers CDL1 and CDL2 may be blocked, so that it may be possible to prevent the adjacent conductive layers CDL1 and CDL2 from being connected with each other due to damage to the insulating film BR2, for example.

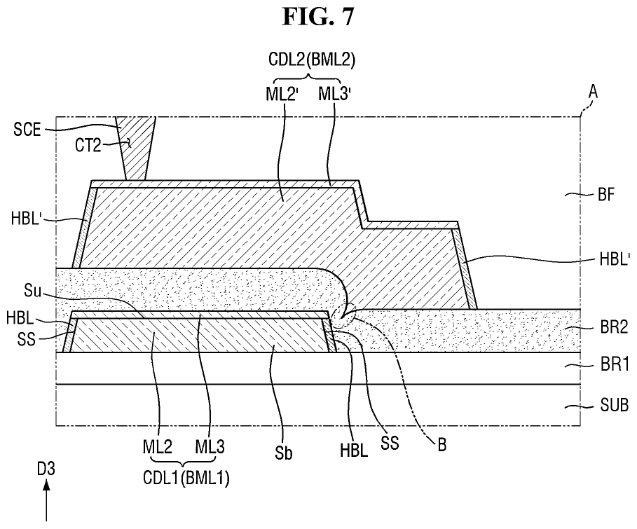

FIG. 7 is an enlarged view of portion A of the display device according to an embodiment of FIG. 4.

The display device of FIG. 7 may be different from the display device of FIG. 5 described above in the structure of conductive layers. The description will focus on the difference.

As shown in FIG. 7, the first conductive layer CDL1 may include a second metal layer ML2 and a third metal layer ML3. For example, the first light-blocking layer BML1 of the first conductive layer CDL1 may include the second metal layer ML2 and the third metal layer ML3 sequentially stacked on the first barrier layer BR1 in the third direction D3.

A blocking film HBL of FIG. 7 may be disposed on the side surfaces Ss of the second metal layer ML2. The blocking film HBL of FIG. 7 may be substantially identical to the above-described blocking film HBL of FIG. 5, and, therefore, the redundant descriptions will be omitted. It should be noted that since the first conductive layer CDL1 of FIG. 7 does not include the first metal layer ML1, for example, the blocking film HBL of FIG. 7 may surround the second metal layer ML2 at the first barrier layer BR1 and the edges of the third metal layer ML3.

According to an embodiment of the disclosure, as shown in FIG. 7, the second metal layer ML2 of the first conductive layer CDL1 may be surrounded by the first barrier layer BR1, the third metal layer ML3, and the blocking film HBL. In other words, the second metal layer ML2 may be disposed in a defined area surrounded by the first barrier layer BR1, the third metal layer ML3, and the blocking film HBL (hereinafter referred to as a fifth shielded area). Accordingly, the second metal layer ML2 in the fifth shielded area may be isolated from the outside of the fifth shielded area by the first barrier layer BR1, the third metal layer ML3, and the blocking film HBL.

The second conductive layer CDL2 and the first conductive layer CDL1 of FIG. 7 may have a same structure. For example, the second light-blocking layer BML2 of the second conductive layer CDL2 may include a second metal layer ML2′ and a third metal layer ML3′. The second metal layer ML2′ and the third metal layer ML3′ of the second conductive layer CDL2 may be identical to the second metal layer ML2 and the third metal layer ML3 of the first conductive layer CDL1, respectively; and, therefore, the redundant descriptions will be omitted.

A blocking film HBL′ surrounding the side surfaces of the second metal layer ML2′ of the second conductive layer CDL2 is identical to the blocking film HBL surrounding the side surfaces Ss of the second metal layer ML2 of the first conductive layer CDL1 of FIG. 7, and, therefore, the redundant descriptions will be omitted.

The second metal layer ML2′ of the second conductive layer CDL2 may be disposed in a defined area surrounded by the second barrier layer BR2, the third metal layer ML3′, and the blocking film HBL′ of the second conductive layer CDL2 (hereinafter referred to as a sixth shielded area). Accordingly, the second metal layer ML2′ in the sixth shielded area may be isolated from the outside of the sixth shielded area by the second barrier layer BR2, the third metal layer ML3′, and the blocking film HBL′.

As described above, since the second metal layer ML2 in the fifth shielded area and the second metal layer ML2′ in the sixth shielded area are shielded from the outside, the hydrogen path between the second metal layer ML2 of the fifth shielded area and the second metal layer ML2′ of the sixth shielded area may be blocked even though the first conductive layer CDL1 and the second conductive layer CDL2 are disposed adjacent to each other and overlap each other in the third direction D3. Therefore, even if a hydrogen path is formed due to damage in an insulating film (e.g., the second barrier layer BR2) between the first conductive layer CDL1 and the second conductive layer CDL2 (e.g., seam, crack or pinhole at area B in the second barrier layer BR2), it may be possible to block movement of hydrogen from the second metal layer ML2 of the first conductive layer CDL1 to the second metal layer ML2′ of the second conductive layer CDL2 (or from the second metal layer ML2′ of the second conductive layer CDL2 to the second metal layer ML2 of the first conductive layer CDL1).

According to an embodiment of the disclosure, the hydrogen path between the adjacent conductive layers CDL1 and CDL2 may be blocked, so that it may be possible to prevent the adjacent conductive layers CDL1 and CDL2 from being connected with each other due to damage to the insulating film BR1, for example.

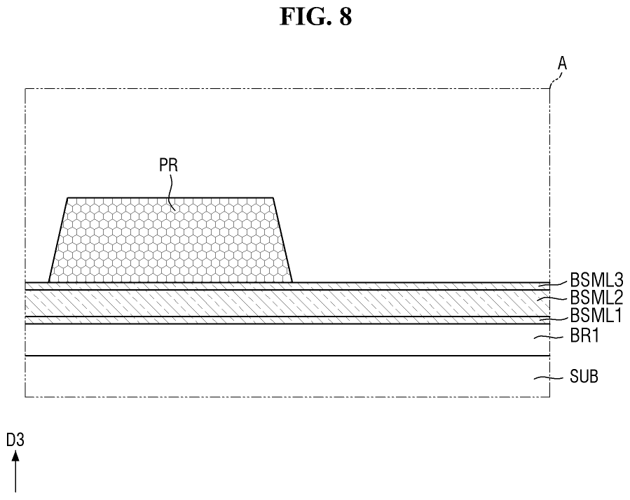

FIGS. 8 to 12 are schematic cross-sectional views for illustrating a method of fabricating a display device according to an embodiment of the disclosure.

As shown in FIG. 8, a first barrier layer BR1 may be disposed on a substrate, and a first base metal layer BSML1, a second base metal layer BSML2 and a third base metal layer BSML3 may be disposed on the first barrier layer BR1 in this order. For example, the first base metal layer BSML1, the second base metal layer BSML2, and the third base metal layer BSML3 may be sequentially disposed on the entire surface of the substrate. Subsequently, a photoresist pattern PR may be disposed on the third base metal layer BSML3.

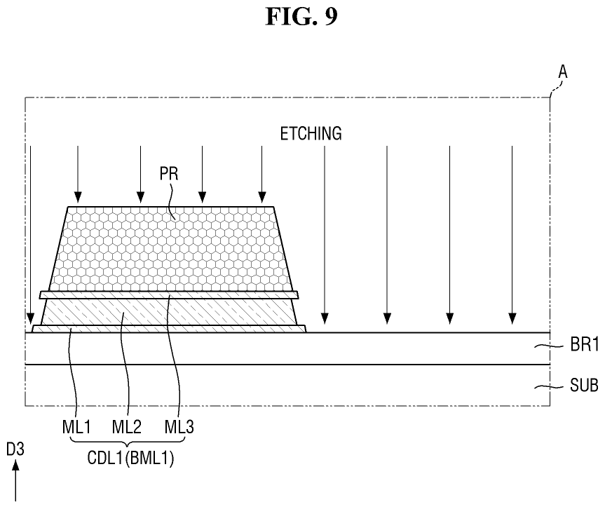

Subsequently, as shown in FIG. 9, the first base metal layer BSML1, the second base metal layer BSML2, and the third base metal layer BSML3 may be etched using the photoresist pattern PR as a mask, thereby forming a first conductive layer CDL1. For example, the first base metal layer BSML1, the second base metal layer BSML2, and the third base metal layer BSML3 may be etched, and a first metal layer ML1, a second metal layer ML2, and a third metal layer ML3 may be formed.

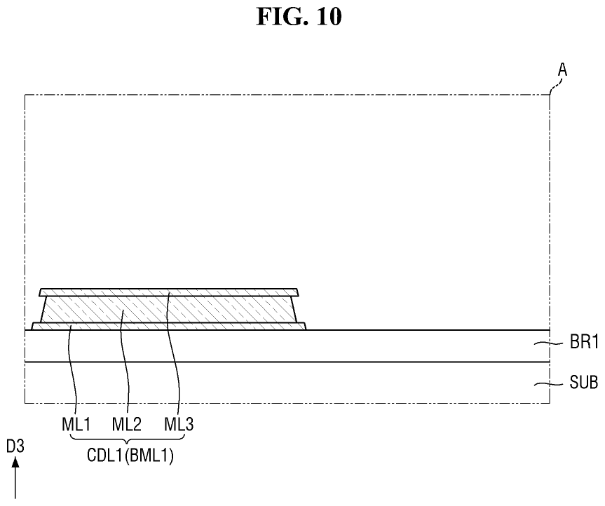

Subsequently, as shown in FIG. 10, the photoresist pattern PR may be removed.

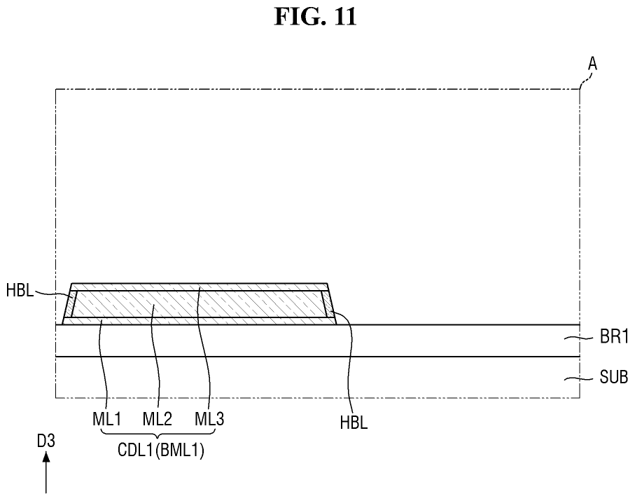

As shown in FIG. 11, a blocking film HBL may be disposed along side surfaces of the second metal layer ML2. The blocking film HBL may be formed, for example, by the anodic oxidation described above.

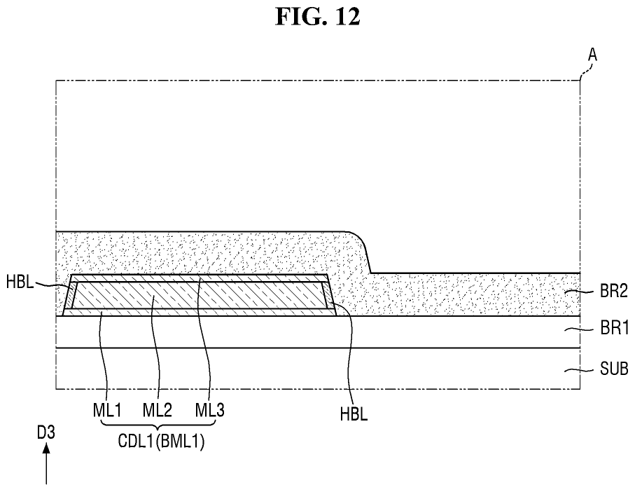

Subsequently, as shown in FIG. 12, a second barrier layer BR2 may be disposed over the first conductive layer CDL1 and the first barrier layer BR1.

Subsequently, a second conductive layer CDL2 may be disposed on the second barrier layer BR2. The method of forming the second conductive layer CDL2 may be identical to the method of forming the first conductive layer CDL1 as shown in FIGS. 8 to 11 described above.

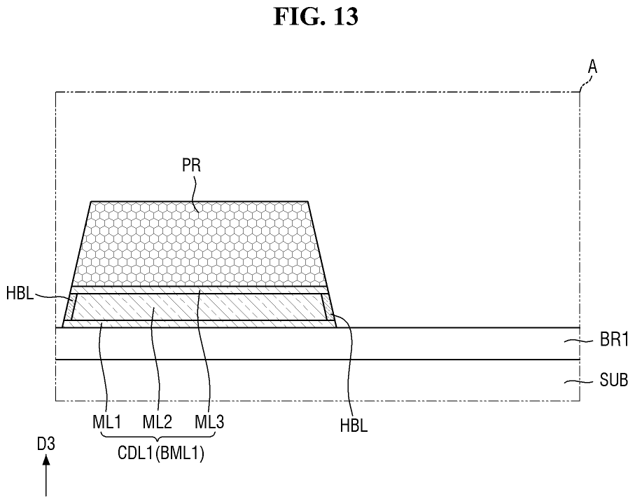

FIG. 13 is a schematic cross-sectional view for illustrating a method of fabricating a display device according to an embodiment of the disclosure.

As shown in FIG. 13, a blocking film HBL may be disposed on the side surfaces of the second metal layer ML2 without the photoresist pattern PR being removed. For example, after the process shown in FIGS. 8 and 9, the process of FIG. 13 may be performed instead of the process of FIG. 10. Subsequently, the photoresist pattern PR may be removed with the blocking film HBL disposed.

The method of fabricating the display device described above with reference to FIGS. 8 to 13 may be, for example, the method of fabricating the display device of FIG. 5 described above.

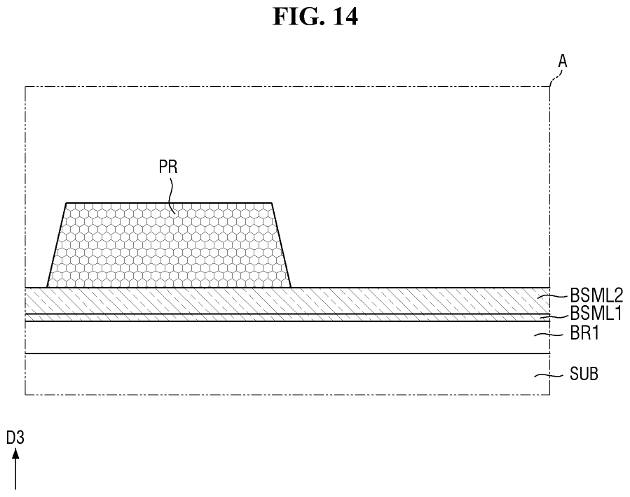

FIGS. 14 to 18 are schematic cross-sectional views for illustrating a method of fabricating a display device according to an embodiment of the disclosure.

As shown in FIG. 14, a first barrier layer BR1 may be disposed on a substrate, and a first base metal layer BSML1 and a second base metal layer BSML2 may be disposed on the first barrier layer BR1 in this order. For example, the first base metal layer BSML1 and the second base metal layer BSML2 may be sequentially disposed on the entire surface of the substrate. Subsequently, a photoresist pattern PR may be disposed on the second base metal layer BSML2.

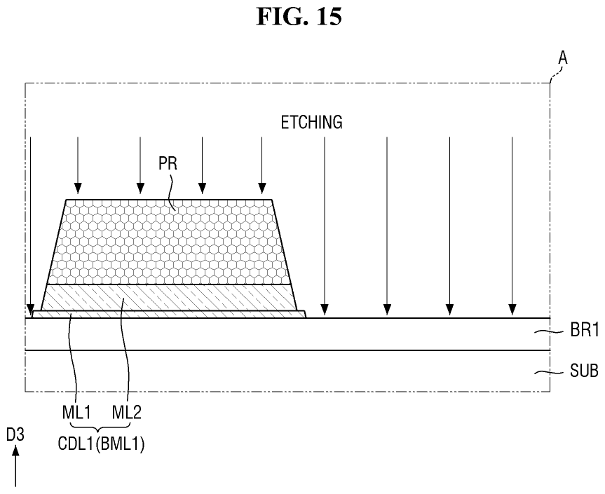

Subsequently, as shown in FIG. 15, the first base metal layer BSML1 and the second base metal layer BSML2 may be etched using the photoresist pattern PR as a mask, thereby forming a first conductive layer CDL1. For example, the first base metal layer BSML1 and the second base metal layer BSML2 may be etched, and a first metal layer ML1 and a second metal layer ML2 may be formed.

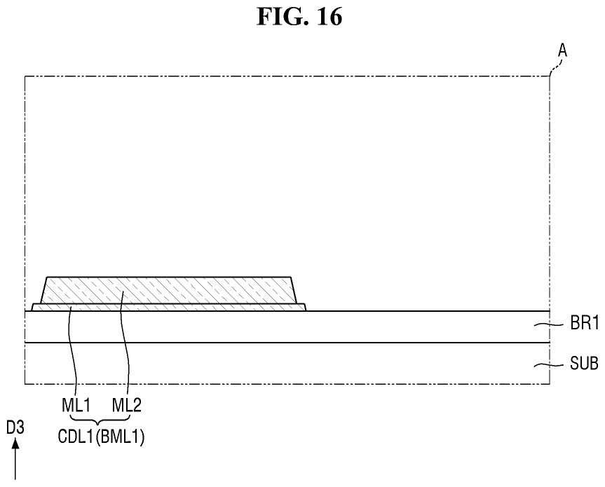

Subsequently, as shown in FIG. 16, the photoresist pattern PR may be removed.

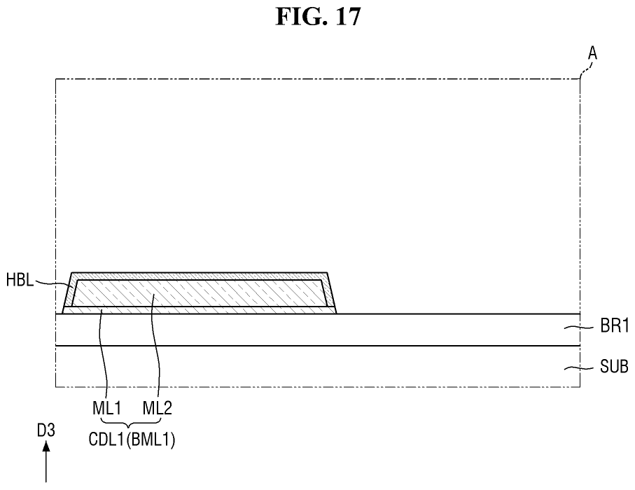

As shown in FIG. 17, a blocking film HBL may be disposed along upper and side surfaces of the second metal layer ML2. The blocking film HBL may be formed, for example, by the anodic oxidation described above.

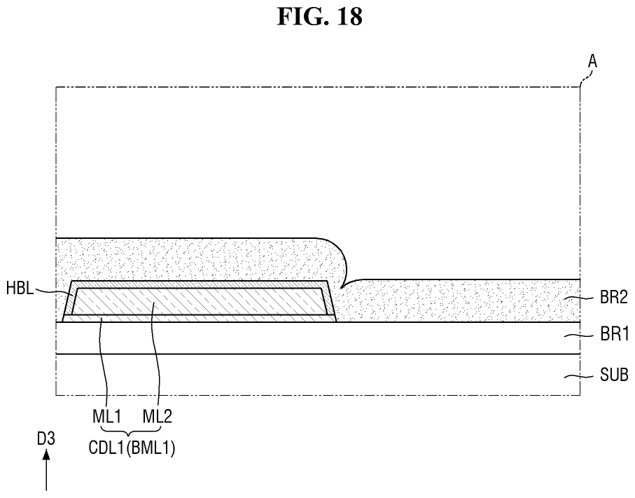

Subsequently, as shown in FIG. 18, a second barrier layer BR2 may be disposed over the blocking film HBL and the first barrier layer BR1.

Subsequently, a second conductive layer CDL2 may be disposed on the second barrier layer BR2. The method of forming the second conductive layer CDL2 may be identical to the method of forming the first conductive layer CDL1 as shown in FIGS. 14 to 17 described above.

The method of fabricating the display device described above with reference to FIGS. 14 to 17 may be, for example, the method of fabricating the display device of FIG. 6 described above.

The method of fabricating the display device of FIG. 7 is substantially identical to the method of fabricating the display device of FIG. 5 described above with reference to FIGS. 8 to 13 except that the first base metal layer BSML1 is eliminated, and, therefore, the redundant descriptions will be omitted.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first conductive layer disposed on a substrate and comprising at least two metal layers;
a first insulating film on the first conductive layer;
a transistor on the first insulating film;
a pixel electrode on the transistor;
an emissive layer on the pixel electrode;
a common electrode on the emissive layer; and
a first blocking film disposed on a side surface of one of the at least two metal layers of the first conductive layer.

2. The display device of claim 1, wherein the at least two metal layers comprise:
a first metal layer on the substrate;
a second metal layer on the first metal layer; and
a third metal layer on the second metal layer.

3. The display device of claim 2, wherein the first blocking film is disposed on a side surface of the second metal layer.

4. The display device of claim 3, wherein the first blocking film surrounds the side surface of the second metal layer in a plan view.

5. The display device of claim 3, wherein the first blocking film is disposed on the side surface of the second metal layer between edges of the first metal layer and edges of the third metal layer.

6. The display device of claim 3, wherein the second metal layer is surrounded by the first metal layer, the third metal layer, and the first blocking film.

7. The display device of claim 2, wherein
each of the first metal layer and the third metal layer includes titanium, and
the second metal layer includes aluminum.

8. The display device of claim 1, wherein the at least two metal layers comprise:
a first metal layer on the substrate; and
a second metal layer on the first metal layer.

9. The display device of claim 8, wherein the first blocking film is disposed on a side surface of the second metal layer.

10. The display device of claim 9, wherein the first blocking film is further disposed on an upper surface of the second metal layer.

11. The display device of claim 10, wherein the first blocking film surrounds the side surface of the second metal layer in a plan view.

12. The display device of claim 10, wherein the first blocking film is disposed on the side surface of the second metal layer at edges of the first metal layer.

13. The display device of claim 10, wherein the second metal layer is surrounded by the first metal layer and the first blocking film.

14. The display device of claim 1, wherein the at least two metal layers comprise:
a first metal layer on the substrate; and
a second metal layer on the first metal layer.

15. The display device of claim 14, wherein the first blocking film is disposed on a side surface of the first metal layer.

16. The display device of claim 15, wherein the first blocking film surrounds the side surface of the first metal layer in a plan view.

17. The display device of claim 15, wherein the first blocking film is disposed on the side surface of the first metal layer at edges of the second metal layer.

18. The display device of claim 15, further comprising:
a second insulating film disposed between the substrate and the first conductive layer,
wherein the first metal layer is surrounded by the second insulating film, the second metal layer, and the first blocking film.

19. The display device of claim 1, further comprising:
a second conductive layer on the first insulating film.

20. The display device of claim 19, wherein the second conductive layer overlaps the first conductive layer in a plan view.

21. The display device of claim 19, wherein the second conductive layer comprises at least two metal layers.

22. The display device of claim 21, further comprising:
a second blocking film disposed on a side surface of one of the at least two metal layers of the second conductive layer.
